(19) United States
(12) Patent Application Publication
(10) Pub. No.: US 2026/0129842 A1
(43) Pub. Date: May 7, 2026

(54) SEMICONDUCTOR DEVICE

(71) Applicant: Samsung Electronics Co., Ltd., Suwon-si (KR)

(72) Inventors: Jungmin Park, Suwon-si (KR); Beom-Jong Kim, Suwon-si (KR); Hyungsuk Jung, Suwon-si (KR)

(73) Assignee: Samsung Electronics Co., Ltd., Suwon-si (KR)

(21) Appl. No.: 19/096,374

(22) Filed: Mar. 31, 2025

(30) Foreign Application Priority Data
Nov. 1, 2024 (KR) 10-2024-0153439

(51) Int. Cl. H10B 12/00; H10D 1/68

(52) U.S. Cl. CPC H10B 12/482; H10D 1/711; H10B 12/03

(57) ABSTRACT

A semiconductor device may include a substrate, a bit line extending in a direction perpendicular to the substrate, a plurality of semiconductor patterns having a first end portion connected to the bit line, and extending in a first direction, a first electrode having a first end portion connected to the semiconductor pattern, and extending in the first direction, and a support portion fixing a second end portion of the first electrode, where the second end portion of the first electrode is located within the support portion.

### CROSS-REFERENCE TO RELATED APPLICATION

This present application claims priority to and the benefit under 35 U.S.C. § 119(a)-(d) of Korean Patent Application No. 10-2024-0153439 filed in the Korean Intellectual Property Office on Nov. 1, 2024, the entire disclosure of which is incorporated herein by reference in its entirety.

### FIELD

The present disclosure relates to a semiconductor device.

### BACKGROUND

There is a demand for technology to increase the integration density of semiconductor devices. In the case of conventional two-dimensional semiconductor devices, since integration density may be mainly determined by the area occupied by a unit memory cell, the degree of integration density achieved may be influenced by the technology used to form fine patterns.

However, the very high cost of the equipment and techniques for forming increasingly finer patterns has become prohibitive. Accordingly, three-dimensional semiconductor memory devices having three-dimensionally arranged memory cells have been proposed.

### SUMMARY

The present disclosure provides a semiconductor device having improved integration and improved structural stability.

A semiconductor device may include a substrate, a bit line extending in a direction perpendicular to the substrate, a plurality of semiconductor patterns having a first end portion connected to the bit line, and extending in a first direction, a first electrode having a first end portion connected to the semiconductor pattern, and extending in the first direction, and a support portion fixing a second end portion of the first electrode, where the second end portion of the first electrode is located within the support portion.

A semiconductor device may include a substrate, a bit line extending in a third direction perpendicular to the substrate, a plurality of semiconductor patterns having a first end portion connected to the bit line, and extending in a first direction transverse to the third direction, a support portion extending in the third direction, and a plurality of first electrodes, extending in the first direction, having first end portions connected to respective semiconductor patterns of the plurality of semiconductor patterns and second end portions are located within the support portion.

A semiconductor device may include a substrate, a bit line extending in a third direction perpendicular to the substrate, a plurality of semiconductor patterns having a first end portion connected to the bit line, and extending in a first direction parallel to the substrate, a capacitor connected to the semiconductor pattern, and a support portion located to extend in the third direction, where the capacitor may include a first electrode including a vertical portion extending in the third direction and a pair of horizontal portions extending from the vertical portion in the first direction, a dielectric layer surrounding the first electrode, and a second electrode located on the dielectric layer, where end

portions of a pair of horizontal portions of the first electrode are located within the support portion.

A method for manufacturing a semiconductor device may include obtaining a substrate comprising a bit line extending in a direction perpendicular to the substrate and a plurality of semiconductor patterns having a first end portion connected to the bit line and extending in a first direction, using a mold to form a plurality of first electrodes having first end portions connected to respective semiconductor patterns of the plurality of semiconductor patterns, exposing second end portions of the plurality of first electrodes by etching a portion of the mold, forming a support portion so that the second end portions of the plurality of first electrodes are located within the support portion; and etching the mold.

Forming the plurality of first electrodes may be performed using atomic layer deposition (ALD).

Upon being formed, a thickness of the support portion along the first direction may be 50 Å to 200 Å.

The support portion may comprise metal nitride, metal oxide or metal carbide, and the metal is Si, Ti, Ta, Hf, Zr or Sr.

Forming the support portion may comprise forming a plurality of support portions located to be spaced apart in a second direction transverse to the first direction.

The method may further comprise forming a plurality of dielectric layers surrounding respective electrodes of the plurality of first electrodes and forming a plurality of second electrodes on the plurality of dielectric layers.

Upon being formed, the support portion may extend in the direction perpendicular to the substrate.

According to embodiments, a semiconductor device having improved integration and improved structural stability may be provided.

### BRIEF DESCRIPTION OF THE DRAWINGS

FIG. 1 briefly illustrates a cross-section of a semiconductor device according to an embodiment.

FIG. 2 and FIG. 3 are enlarged views of a region indicated as A in FIG. 1.

FIG. 4 is a cross-section taken along line I-I′ of FIG. 3.

FIG. 5 is a cross-section taken along line II-II′ of FIG. 4.

FIG. 6 is a cross-section taken along line III-III′ of FIG. 3.

FIG. 7 illustrates the same cross-section as FIG. 5 with respect to another embodiment.

FIG. 8 illustrates the same region as FIG. 2 with respect to a semiconductor device that does not include a support portion.

FIG. 9 illustrates the same cross-section as FIG. 8 with respect to another embodiment.

FIG. 10 illustrates the same cross-section as FIG. 9 with respect to a semiconductor device according to an embodiment.

FIG. 11 to FIG. 14 briefly illustrates a manufacturing method of a semiconductor device according to an embodiment.

FIG. 15 is a perspective view schematically showing a semiconductor device according to an embodiment.

FIG. 16 is a cross-sectional view of a semiconductor device according to an embodiment.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

In the drawings, the thicknesses of layers, films, panels, regions, areas, etc., are exaggerated for clarity. Like reference numerals designate like elements throughout the specification. It will be understood that when an element such as a layer, film, region, area or substrate is referred to as being “on” or “above” another element, it can be directly on the other element or intervening elements may also be present. In contrast, when an element is referred to as being “directly on” another element, there are no intervening elements present.

The inventors have recognized and appreciated that conventional memory devices including memory cells that are stacked on one another in the vertical direction and that include elongated electrodes extending in a lateral direction suffer from sagging, a phenomenon whereby those electrodes sag downwardly due to their weight. The sagging effect may be exacerbated by the presence of dielectric layers formed on top of those electrodes because the dielectric layers increase the weight that each electrode has to withstand. Further, while increasing the length of those electrodes is beneficial in some circumstances because it increases their capacitance, the larger extension further exacerbates the sagging effect. When an electrode sags downward as such, it may come into contact with the neighboring electrode, thereby causing a short circuit.

The inventors have further recognized and appreciated that, due to relatively large lateral extension of those electrodes, grooves may inadvertently be formed during the process of forming those electrodes. The process of forming an electrode may involve a narrow and long open portion of a mold through an atomic layer deposition (ALD) process. Due to the ALD process characteristics, the material that will ultimately define the electrode may not be sufficiently deposited. As a result, a groove may be formed on the edge of an electrode. An etchant or the like may be inadvertently introduced into the groove in a subsequent process, which may cause lifting and defects of the electrode.

The inventors have developed designs that overcome the above-described limitations. First, embodiments of the present disclosure involve fixing the end portions of those electrodes to a common support portion that extends in the vertical direction. Fixing the electrodes to a common support portions prevents the sagging effect. Second, the electrodes are located so that the end portions are disposed within the support portion. In this way, the electrodes are capped by the support portion (e.g., the end portions are covered by the support portion), and etchants that may otherwise penetrate into the grooves in a subsequent process are blocked.

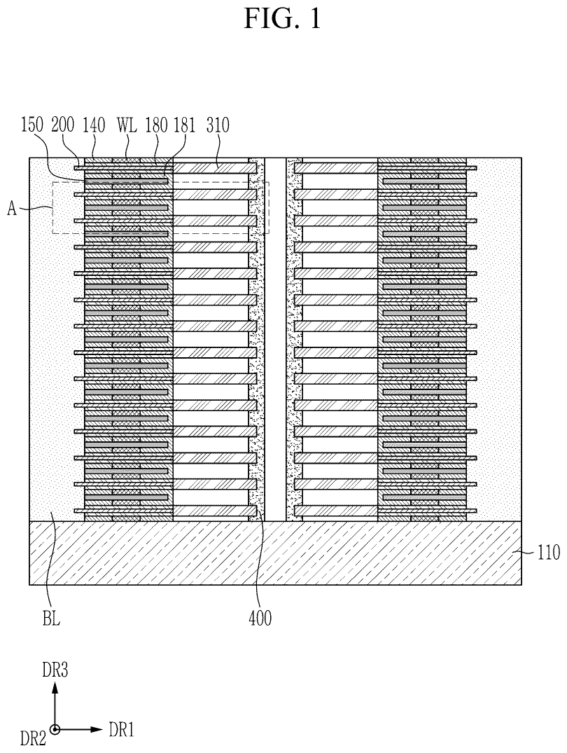

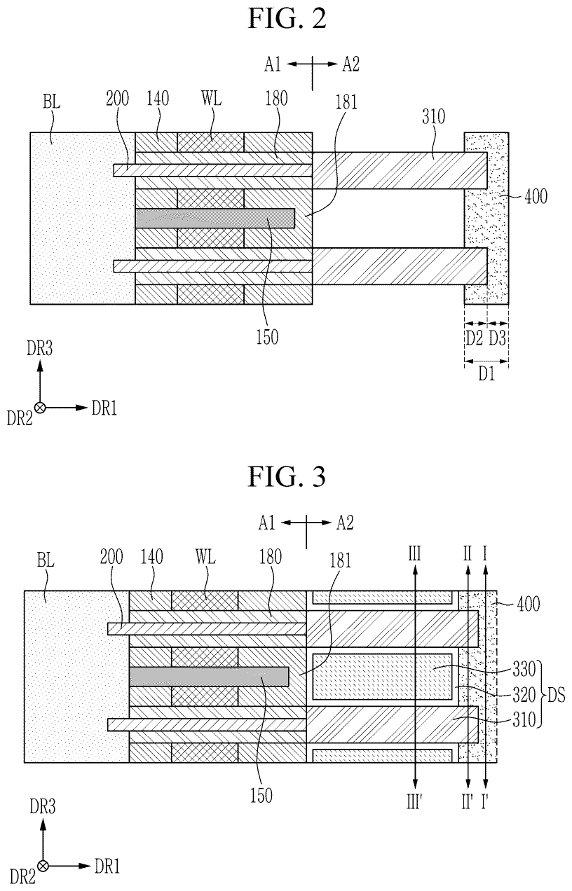

Hereinafter, a semiconductor device according to an embodiment will be described. FIG. 1 briefly illustrates a cross-section of the semiconductor device according to an embodiment. FIG. 2 and FIG. 3 are enlarged views of a region indicated as A in FIG. 1. For better understanding and ease of description, FIG. 1 and FIG. 2 only illustrate a configuration of a first electrode 310 among the data storage patterns, and FIG. 3 illustrates all configurations of the first electrode 310, a dielectric layer 320 and a second electrode 330, which configure the data storage pattern DS.

Simultaneously referring to FIG. 1 and FIG. 2, a semiconductor device 100 according to an embodiment may include memory cells 3-dimensionally arranged on a substrate 110. The memory cells may be arranged in a first direction DR1, a second direction DR2, and a third direction DR3. Directions DR1, DR2 and DR3 are transverse (e.g., perpendicular) to one another. The first direction DR1 and the second direction DR2 may be a direction parallel to the substrate 110. For example, the second direction DR2 may be a direction perpendicular to the first direction DR1. The third direction DR3 may be a direction perpendicular to the substrate 110. The memory cells may be stacked in the third direction DR3. Each memory cell may be connected to one bit line BL and two word lines WL.

The bit line BL may extend along the third direction DR3. The memory cells stacked in the third direction DR3 may be commonly connected to the one bit line BL.

The word line WL may extend along the second direction DR2. The memory cells arranged along the second direction DR2 may be commonly connected to one word line WL. A plurality of word lines WL may be arranged along the third direction DR3. Each memory cell may be connected to the adjacent two word lines WL arranged in the third direction DR3.

An interlayer insulating layer 150 may be located between the word lines WL neighboring in the third direction DR3. The interlayer insulating layer 150 may include an insulating material, and may insulate the word line WL neighboring in the third direction DR3. The word line WL in upper layer of the interlayer insulating layer 150 and the word line WL in a lower layer of the interlayer insulating layer 150 may be spaced apart in the third direction DR3 by the interlayer insulating layer 150. The interlayer insulating layer 150 may include at least one of silicon nitride layer, silicon oxide nitride layer, carbon-containing silicon oxide layer, carbon-containing silicon nitride layer, or carbon-containing silicon oxide nitride layer.

A spacer 140 may be located between the word line WL and the bit line BL. The spacer 140 may include an insulating material, and may insulate the bit line BL and the word line WL from each other.

Referring to FIG. 1 and FIG. 2, a semiconductor pattern 200 may be located between the two word lines WL. The semiconductor pattern 200 may extend in the first direction DR1. A first end of the semiconductor pattern 200 may be connected to the bit line BL, and second end may be connected to the first electrode 310. The semiconductor pattern 200 may include silicon, germanium, silicon-germanium, or indium gallium zinc oxide (IGZO). The semiconductor pattern 200 may include extrinsic regions and a channel region between the extrinsic regions. The extrinsic regions may correspond to a source/drain region. The extrinsic regions may be regions in which impurities are doped into the semiconductor pattern 200. The extrinsic regions may have either n-type or p-type conductivity. The extrinsic regions may be formed adjacent to both end portions of the semiconductor pattern 200.

A first gate insulation layer 180 may be located between the semiconductor pattern 200 and the word line WL. The semiconductor pattern 200 may be spaced apart from the word line WL by the first gate insulation layer 180. A second gate insulation layer 181 may be located to cover a side surface of the word line WL and a side surface of the interlayer insulating layer 150. As shown in FIG. 1 and FIG. 2, the second gate insulation layer 181 may be located in contact with the first gate insulation layer 180, the word line WL and the interlayer insulating layer 150. However, the shapes of the first gate insulation layer 180, the second gate insulation layer 181, the interlayer insulating layer 150 disclosed in FIG. 1 and FIG. 2 are merely an example, and the present disclosure is not limited thereto. That is, depending on the embodiment, the shapes of the first gate insulation layer 180, the second gate insulation layer 181, the interlayer insulating layer 150 may vary. In an embodiment, a width of the first gate insulation layer 180 may be different for each region. In addition, FIG. 1 to FIG. 3 illustrate a configuration in which an edge of the first gate insulation layer 180 coincides with an edge of the semiconductor pattern 200, but this is merely an example, and the present disclosure is not limited thereto. In an embodiment, an edge of the first gate insulation layer 180 may be located to protrude in the first direction DR1 more than the edge of the semiconductor pattern 200, and a partial region of the first electrode 310 may be located in a space between the first gate insulation layers 180.

The first gate insulation layer 180 and the second gate insulation layer 181 may include at least one of a high-k dielectric layer, a silicon oxide layer, a silicon nitride layer, or a silicon oxide nitride layer. The high-k dielectric layer may include, for example, at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate. The first gate insulation layer 180 and the second gate insulation layer 181 may include the same material, and may include different materials.

Referring to FIG. 2 and FIG. 3, the semiconductor device according to the present embodiment may include a transistor portion A1 and a data storage portion A2. The transistor portion A1 may be a region where the bit line BL, the semiconductor pattern 200, and the word line WL are located, and the data storage portion A2 may be a region where the data storage pattern DS is located. The shape of the transistor portion A1 described with reference to FIG. 1 to FIG. 3 is merely an example, and the present disclosure is not limited thereto.

Then, hereinafter, the structure of the data storage portion A2 will be described. Referring to FIG. 1 to FIG. 3, the first electrode 310 may be located to extend in the first direction DR1. Referring to FIG. 1 to FIG. 3, each first electrode 310 may be connected to the semiconductor pattern 200. For better understanding and ease of description, FIG. 1 to FIG. 3 briefly illustrate a shape of the first electrode 310, but the form in which the first electrode 310 and the transistor portion A1 are connected may vary.

This specification illustrates the configuration in which, edges of the semiconductor pattern 200 and the first gate insulation layer 180 coincide, and the first electrode 310 is located in contact with the semiconductor pattern 200. However, in an embodiment, first end of the first gate insulation layer 180 may be located to protrude more than the first end of the semiconductor pattern 200, and the portion of the semiconductor pattern 200 may be located between the first gate insulation layers 180. That is, in the cross-section of FIG. 3, the semiconductor pattern 200 and the first electrode 310 may be located between the first gate insulation layers 180 neighboring in the third direction DR3.

The first electrode 310 may include at least one of a metallic material such as titanium, tantalum, tungsten, copper, or aluminum, a conductive metal nitride such as titanium nitride or tantalum nitride, or a doped semiconductor material such as doped silicon or doped germanium.

A support portion 400 may be located to a first end of the first electrode 310. Referring to FIG. 1, the support portion 400 may be located to extend along the third direction DR3. As shown in FIG. 1 to FIG. 3, the support portion 400 may fix the first electrode 310. The first end of the first electrode 310 may be cover by the support portion 400. As will be explained separately later, the support portion 400 may fix the first electrode 310, thereby solving the problem that the first electrode 310 extending in the first direction DR1 sags downward or becomes in contact with another neighboring first electrode 310.

The support portion 400 may include an insulating material. For example, it may include a metal nitride, a metal oxide, or a metal carbide. The metal may be Si, Ti, Ta, Hf, Zr or Sr. That is, the support portion may include a nitride, oxide, or carbide of Si, Ti, Ta, Hf, Zr, or Sr.

Referring to FIG. 2, a thickness D1 of the support portion 400 along the first direction DR1 may be 50 Å to 200 Å. When the thickness of the support portion is less than 50 Å, the first electrode 310 may not be sufficiently supported, and when the thickness D1 of the support portion is 200 Å or more, an area of the data storage pattern may decrease, thereby decreasing the efficiency.

In addition, in the support portion 400, a width D2 of a region overlapping with the first electrode 310 may be wider than a width D3 of a region that does not overlap with the first electrode 310. Accordingly, the first electrode 310 may be stably fixed.

As shown in FIG. 2, the first end of the first electrode 310 may be cover by the support portion 400. That is, an edge of the first electrode 310 may not be exposed. Since an end point of the first electrode 310 is covered by the support portion 400 as such, during the forming process of the first electrode 310, a groove formed in the first electrode 310 may be capped. Therefore, as will be explained separately later, an etchant may be prevented from being introduced into the groove of the first electrode 310 during the manufacturing process.

FIG. 3 illustrates all of the first electrode 310, the dielectric layer 320 and the second electrode 330 in the same cross-section as FIG. 2. Referring to FIG. 3, the first electrode 310, the dielectric layer 320 and the second electrode 330 may configure the data storage pattern DS.

The data storage pattern DS may be electrically connected to the semiconductor pattern 200. The data storage pattern DS is a memory element capable of storing data, and may be, for example, a memory element using a capacitor, a memory element using a magnetic tunnel junction pattern, or a memory element using a variable resistor including a phase-change material. According to an embodiment, the data storage pattern DS may be a capacitor. According to an embodiment, the data storage pattern DS may include the first electrode 310, the second electrode 330 spaced apart from the first electrode 310, and the dielectric layer 320 located between the first electrode 310 and the second electrode 330.

The dielectric layer 320 may located along surfaces of the first electrode 310 and the support portion 400. The dielectric layer 320 may be located to surround a front surface of the first electrode 310. The dielectric layer 320 may include at least one of a dielectric material, a ferromagnetic material, or an antiferromagnetic material. The dielectric material may include a high-k material. For example, the dielectric material may include hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or a combination thereof.

The second electrode 330 may be located to fill the space between the first electrodes 310. The second electrode 330 may include at least one of a metallic material such as titanium, tantalum, tungsten, copper, or aluminum, a conductive metal nitride such as titanium nitride or tantalum nitride, or a doped semiconductor material such as doped silicon or doped germanium. The second electrode 330 of a plurality of data storage patterns DS may be integrally connected. Although not shown in FIG. 3, the dielectric layer 320 and the second electrode 330 may be located in a space between the support portions 400 neighboring to each other illustrated in FIG. 1.

The semiconductor device according to the present embodiment may fix the first end of the first electrode 310 by the support portion 400, thereby preventing sagging of the first electrode 310 and contact with another first electrode 310. Hereinafter, a structure of the semiconductor device according to the present embodiment will be described with a focus on the cross-section.

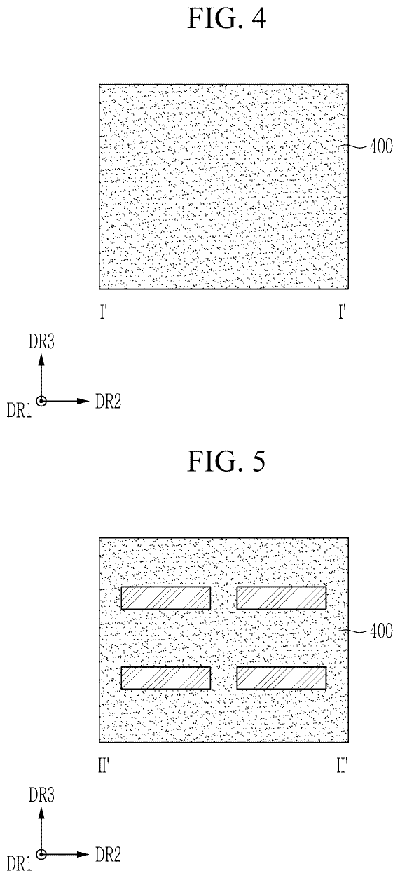

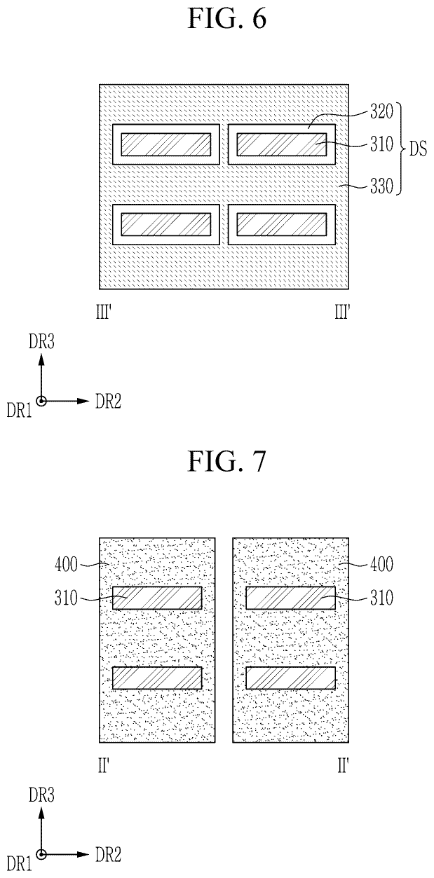

FIG. 4 is a cross-section taken along line I-I′ of FIG. 3, and FIG. 5 is a cross-section taken along line II-II′ of FIG. 4, and FIG. 6 is a cross-section taken along line III-III′ of FIG. 3.

Referring to FIG. 3 and FIG. 4, the end point of the first electrode 310 is covered by the support portion 400, and the first electrode 310 may not protrude or be exposed outside the support portion 400. Accordingly, as will be explained separately later, an etchant or the like may be prevented from being introduced into the groove of the first electrode 310.

In addition, referring to the cross-section of FIG. 5, the first electrode 310 may be fixed by being surrounded by the support portion 400. Accordingly, the first electrode 310 may be prevented from sagging downward due to the load or from being in contact with another neighboring first electrode 310.

In addition, referring to the cross-section of FIG. 6, the data storage pattern DS may include the first electrode 310, the dielectric layer 320 surrounding the first electrode 310, and the second electrode 330. As shown in FIG. 6, the first electrode 310 may be located for each data storage pattern DS, respectively, and the second electrode 330 may be commonly located to the plurality of data storage patterns DS.

FIG. 4 to FIG. 6 illustrate an embodiment in which the support portion 400 is located in the form of a single plate, but in another embodiment, the support portion 400 may be located in a plurality of separated pieces. FIG. 7 illustrates the same cross-section as FIG. 5 with respect to another embodiment. Referring to FIG. 7, in the semiconductor device according to the present embodiment, the support portion 400 may extend in the third direction DR3, and may be separated in the second direction DR2. That is, a plurality of first electrodes 310 neighboring in the third direction DR3 are fixed to the same support portion 400, and the plurality of first electrodes 310 neighboring in the second direction DR2 may be fixed to another support portion 400. However, the shape of the support portion 400 may be an example, and the present disclosure is not limited thereto. Although FIG. 7 illustrates a configuration in which the support portion 400 extends in the third direction DR3 and located to be separated in the second direction DR2, in another embodiment, the support portion 400 may extend along the second direction DR2 and be located to be separated in the third direction DR3.

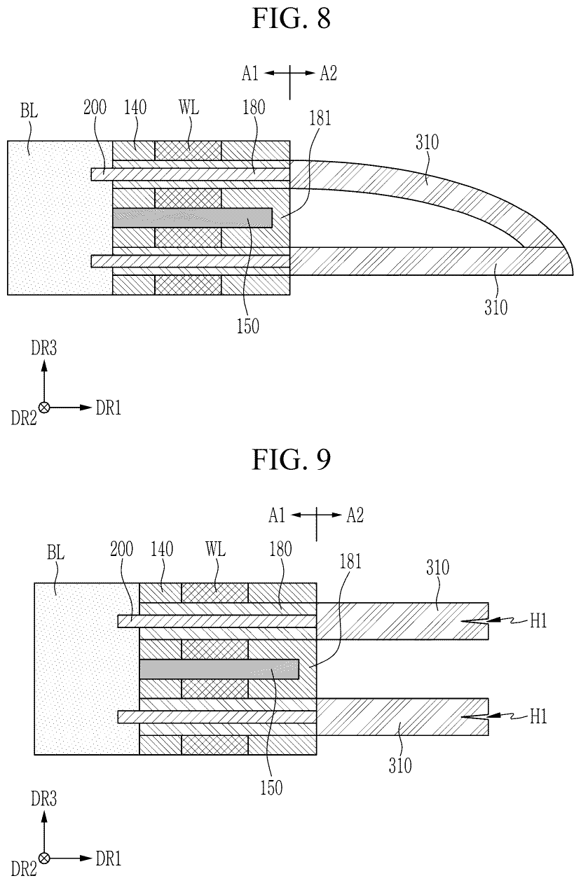

Then, hereinafter, an effect of the semiconductor device according to the present embodiment will be described with reference to the drawings. FIG. 8 illustrates the same region as FIG. 2 with respect to the semiconductor device that does not include the support portion 400. Referring to FIG. 8, the first electrode 310 during the manufacturing process extends in the first direction DR1. At this time, since the first electrode 310 is located to be elongated in the first direction DR1, the first electrode 310 may sag downward due to the weight of the first electrode 310. In addition, the first electrode 310 may sag downward due to the load occurring in the process when a subsequent process such as forming the dielectric layer on the first electrode 310 is performed. When the first electrode 310 sags downward as such, it may be in contact with another neighboring first electrode 310. When a length of the first electrode 310 becomes longer for an increase of capacitance, the sagging problem of the first electrode 310 may occur more easily. This may cause a short circuit between neighboring first electrodes 310, and is not preferable.

In addition, since the first electrode 310 has a structure that extends to be lengthy in the first direction DR1, during the forming process of the first electrode 310, the first electrode 310 may not be sufficiently formed so that the groove may be formed. FIG. 9 illustrates the same cross-section as FIG. 8 with respect to another embodiment. Referring to FIG. 9, a groove H1 may be formed on the edge of the first electrode 310. When forming the first electrode 310, the first electrode 310 may be formed within a narrow and long open portion of a mold through an atomic layer deposition (ALD) process. At this time, due to the ALD process characteristics, the first electrode 310 material may not be sufficiently deposited, and the groove H1 may be formed in a corresponding region. An etchant or the like may be introduced into the groove H1 in a subsequent process, which may cause lifting and defects of the first electrode 310.

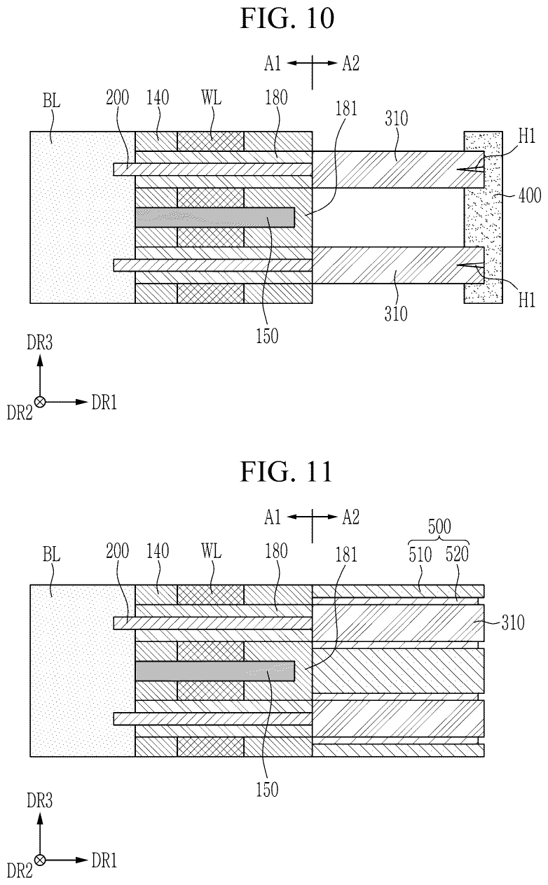

However, according to the semiconductor device according to the present embodiment, the support portion 400 may fix and cap the first electrode 310. FIG. 10 illustrates the same cross-section as FIG. 9 with respect to the semiconductor device according to an embodiment. Referring to FIG. 10, the groove H1 of the first electrode 310 is capped by the support portion 400. That is, since the end point of the first electrode 310 is not exposed but covered by the support portion 400, an etchant may be prevented from being introduced into the groove of the first electrode 310 H1 in a subsequent process.

Then, hereinafter, a manufacturing method of the semiconductor device according to the present embodiment will be described with reference to the drawings. FIG. 11 to FIG. 14 briefly illustrate a manufacturing method of the semiconductor device according to an embodiment. FIG. 11 to FIG. 14 illustrate a cross-section of the same region as FIG. 2, focusing on forming process of the data storage portion A2.

Referring to FIG. 11, a mold 500 may be formed in the region of the data storage portion A2, and may form the first electrode 310 inside the mold 500. At this time, the mold 500 may include a first portion 510 and a second portion 520. The second portion 520 may include an oxide, but is not limited thereto. The second portion 520 may be in direct contact with the first electrode 310. The mold 500 may located along the first direction DR1, and may include an open portion extending along the first direction DR1. The first electrode 310 may be formed within an open portion of the mold 500. At this time, the first electrode 310 may be formed by an ALD process. At this time, due to the ALD process characteristics, the groove may be formed on a portion where the first electrode 310 is not deposited. When the groove is formed, a shape of an end portion of the first electrode 310 may be the same as shown in FIG. 9. FIG. 11 shows the first electrode 310 where the groove is not formed. As shown in FIG. 11, after forming the first electrode 310, the second portion 520 of the mold 500 may be partially removed.

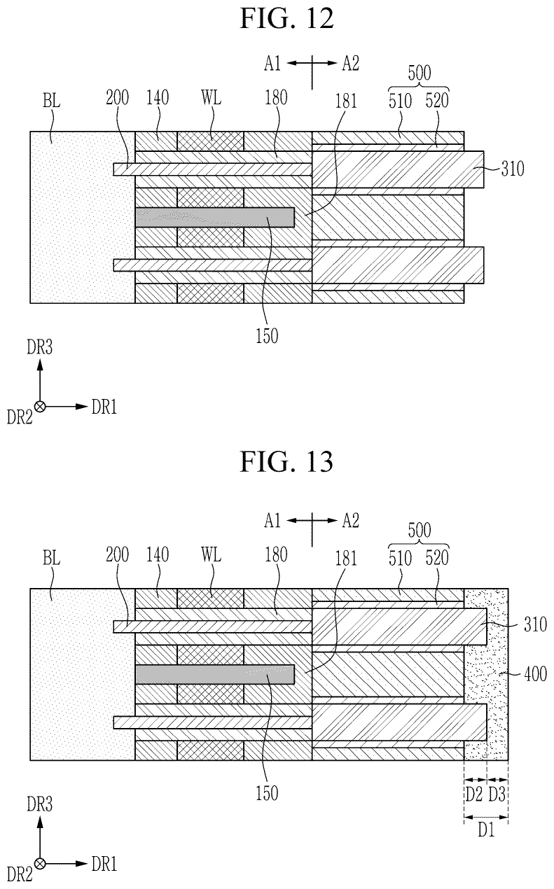

Subsequently, referring to FIG. 12, a portion of the mold 500 may be etched. During this process, a part of the mold 500 having surrounded the first electrode 310 may be removed and a partial region of the first electrode 310 may be exposed.

Subsequently, referring to FIG. 13, the support portion 400 may be formed. The support portion 400 may be formed to cover the first electrode 310 that is not covered by the mold 500. As described above, the support portion 400 may cover the end point of the first electrode 310. That is, by the support portion 400, the end of the first electrode 310 may not be exposed but capped. Accordingly, when the groove is formed during the forming process of the first electrode 310 in the previous step, the groove may be capped by the support portion 400. Accordingly, an etchant or the like used in a subsequent process may not infiltrate into the first electrode 310.

The shape of the support portion 400 formed in this step may be the same as described above. A detailed description on the same components will be omitted. That is, the support portion 400 may be formed to extend in the third direction DR3. At this time, the plurality of first electrodes 310 may be fixed to the support portion 400 in the form of a single plate. The first electrode 310 neighboring in one direction may be fixed to the same support portion 400, and the plurality of first electrodes 310 neighboring in another direction may be fixed by different support portions 400. That is, the support portion 400 formed in this step may be formed in the shape of a single plate or may be formed in a plurality of pieces.

A description of the support portion 400 is the same as described above. A detailed description on the same components will be omitted. The support portion 400 may include an insulating material. For example, it may include a metal nitride, a metal oxide, or a metal carbide. The metal may be Si, Ti, Ta, Hf, Zr or Sr. That is, the support portion may include a nitride, oxide, or carbide material of Si, Ti, Ta, Hf, Zr, or Sr. The thickness D1 of the support portion 400 may be 50 Å to 200 Å. In addition, in the support portion 400, the width D2 of the region overlapping with the first electrode 310 may be wider than the width D3 of the region that does not overlap with the first electrode 310.

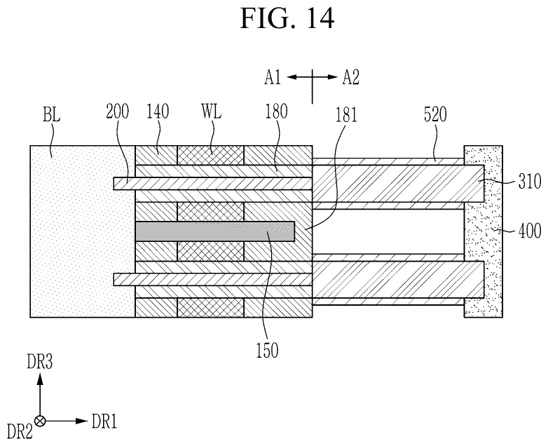

Subsequently, referring to FIG. 14, the first portion 510 of the mold 500 may be removed. Subsequently, although not shown in the drawings, the second portion 520 may be removed, and by forming the dielectric layer and the second electrode in a space where the mold is removed, the semiconductor device as shown in FIG. 3 may be manufactured.

In the above, although a semiconductor device having the first electrode 310 in a pillar shape was described, the semiconductor device according to the present embodiment is not limited to such a structure. For example, the support portion 400 of the present disclosure may be applied to a semiconductor device in which the first electrode 310 has a cylindrical shape. Hereinafter, another embodiment will be described.

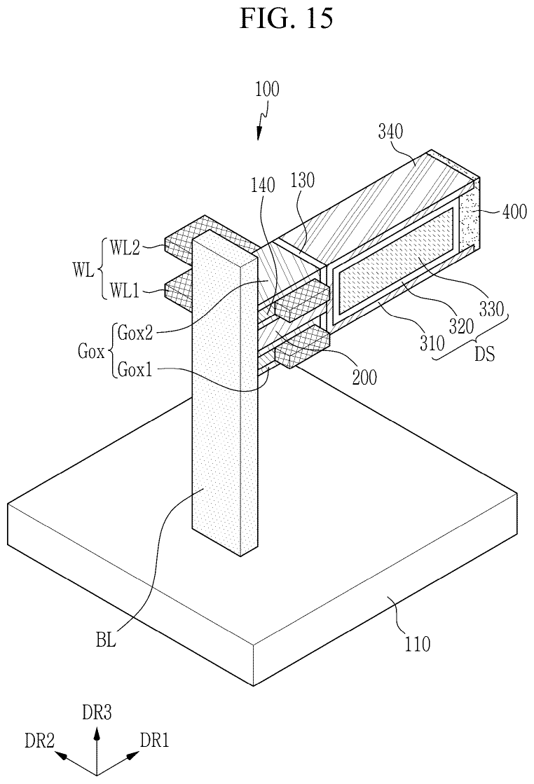

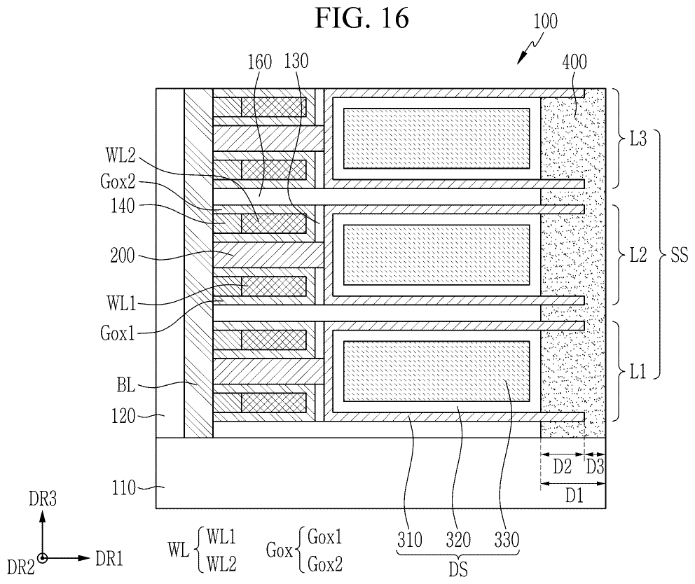

FIG. 15 is a perspective view schematically showing a semiconductor device according to an embodiment. FIG. 16 is a cross-sectional view of a semiconductor device according to an embodiment.

The semiconductor device 100 according to an embodiment may include the memory cells that are 3-dimensionally arranged. The memory cells may be arranged in the first direction DR1, the second direction DR2, and the third direction DR3. The first direction DR1 and the second direction DR2 may be the direction parallel to the substrate 110. For example, the second direction DR2 may be the direction perpendicular to the first direction DR1. The third direction DR3 may be the direction perpendicular to the substrate 110. The memory cells may be stacked in the third direction DR3. Each memory cell may be connected to the one bit line BL and the two word lines WL.

The bit line BL may extend along the third direction DR3. The memory cells stacked in the third direction DR3 may be commonly connected to the one bit line BL.

The word line WL may extend along the second direction DR2. The memory cells arranged along the second direction DR2 may be commonly connected to one word line WL. The plurality of word lines WL may be arranged along the third direction DR3. Each memory cell may be connected to the adjacent two word lines WL arranged in the third direction DR3.

FIG. 15 represents one memory cell and one bit line BL and two word lines WL connected to the one memory cell, and for convenience, omits illustration of other memory cells. FIG. 15 illustrates only one cell of one layer of a stacking structure SS of FIG. 16 to be described later.

FIG. 16 shows three memory cells commonly connected to the one bit line BL and stacked in the third direction DR3. FIG. 16 further illustrates the memory cells arranged in the third direction DR3 that is not shown in FIG. 15. FIG. 16 illustrates that the stacking structure SS includes three layers, but is not limited thereto. According to an embodiment, the stacking structure SS may include more layers. FIG. 16 illustrates that each layer of the stacking structure SS includes one memory cell, but is not limited thereto. According to an embodiment, each layer of the stacking structure SS may include more cells. For example, each layer of the stacking structure SS may further include a memory cell whose structure is mirror-symmetrical to the memory cell shown in FIG. 16. For example, the stacking structure that is mirror-symmetrical to the stacking structure SS of FIG. 16 may be further provided on the substrate 110 in the second direction DR2. The stacking structure SS and the stacking structure that is mirror-symmetrical to the stacking structure SS may form a pair. A pair of stacking structures may share the second electrode 330 of the data storage patterns DS to be described later. Alternatively, the pair of stacking structures may include the second electrode 330, respectively.

Referring to FIG. 15 and FIG. 16, the semiconductor device 100 according to an embodiment may include the substrate 110, the bit line BL extending in the third direction DR3 perpendicular to the substrate 110, a plurality of semiconductor patterns 200 connected to the bit line BL, a pair of word lines WL located above and below each of the plurality of semiconductor patterns 200, and the data storage pattern DS connected to each of the plurality of semiconductor patterns. According to an embodiment, a first end portion of each of the plurality of semiconductor patterns 200 may be connected to the bit line BL, and a second end portion thereof may be connected to the data storage pattern DS.

According to an embodiment, the stacking structure SS may be provided on the substrate 110. The substrate 110 may be, for example, a silicon substrate, a germanium substrate, or a silicon-germanium substrate. The stacking structure SS may configure a memory cell array of the semiconductor device. Although not shown in the drawings, a peripheral circuit for operating the memory cell array may be provided on the substrate 110. Wirings electrically connected to the bit lines BL and the word lines WL may be provided on the stacking structure SS, and wirings may be connected to the peripheral circuit.

The bit line BL and a first interlayer insulating layer 120 may be provided on a first side of the stacking structure SS. The bit line BL may extend in the third direction DR3 perpendicular to the substrate 110. The bit line BL may have a line shape or a column shape extending in the third direction DR3.

The bit line BL may be electrically connected to the semiconductor pattern 200. The bit line BL may be in contact with the semiconductor pattern 200.

The bit line BL may include a conductive material. The conductive material may be, for example, one of a doped semiconductor material such as doped silicon or doped germanium, a conductive metal nitride such as titanium nitride or tantalum nitride, a metal such as tungsten, titanium, or tantalum, or a metal-semiconductor compound such as tungsten silicide, cobalt silicide, or titanium silicide.

The first interlayer insulating layer 120 may extend in the third direction DR3 perpendicular to the substrate 110. In addition, the first interlayer insulating layer 120 may extend along the first direction DR1 parallel to the substrate 110. The first interlayer insulating layer 120 may cover the bit line BL. The first interlayer insulating layer 120 may extend to the space between the bit lines BL arranged along the first direction DR1. By the first interlayer insulating layer 120, the bit lines BL arranged along the first direction DR1 may be insulated from each other.

The first interlayer insulating layer 120 may include, for example, at least one of a silicon nitride layer, silicon oxide nitride layer, carbon-containing silicon oxide layer, carbon-containing silicon nitride layer, or carbon-containing silicon oxide nitride layer.

The stacking structure SS may include a plurality of layers. For example, the stacking structure SS may include a first layer L1, a second layer L2, and a third layer L3 sequentially stacked on the substrate 110. The first layer L1, the second layer L2, and the third layer L3 may be stacked in the third direction DR3 perpendicular to the substrate 110. Each of the first layer L1, the second layer L2, and the third layer L3 may include the semiconductor pattern 200, the pair of word lines WL located above and below the semiconductor pattern 200, and the data storage pattern DS connected to the semiconductor pattern 200.

A second interlayer insulating layers 160 may be located between two adjacent layers. A second interlayer insulating layer 160 may be located between the first layer L1 and the second layer L2, and between the second layer L2 and the third layer L3. The word lines WL, the semiconductor pattern 200, and the data storage pattern DS in each layer may be provided on the second interlayer insulating layer 160. The word lines WL in an upper layer and the word lines WL in a lower layer may be spaced apart in the third direction DR3 by the second interlayer insulating layer 160. The semiconductor pattern 200 in an upper layer and the semiconductor pattern 200 in a lower layer may be spaced apart in the third direction DR3 by the second interlayer insulating layer 160. The data storage pattern DS in an upper layer and the data storage pattern DS in a lower layer may be spaced apart in the third direction DR3 by the second interlayer insulating layer 160.

The second interlayer insulating layer 160 may be located between a lowermost layer of the stacking structure SS and the substrate 110.

The second interlayer insulating layer 160 may include, for example, at least one of a silicon nitride layer, silicon oxide nitride layer, carbon-containing silicon oxide layer, carbon-containing silicon nitride layer, or carbon-containing silicon oxide nitride layer.

The word line WL may extend along the second direction DR2. The word line WL may have a line shape extending in the second direction DR2. Each layer may include the two word lines WL. In each layer, a first word line WL1 and a second word line WL2 may be disposed to be spaced apart from the third direction DR3. For example, the first word line WL1 may be more adjacent to the substrate 110 than the second word line WL2.

The word line WL may include a conductive material. For example, the conductive material may be one of a semiconductor material, a conductive metal nitride, a metal, or a metal-semiconductor compound.

The spacer 140 may be located between the word line WL and the bit line BL. The spacer 140 may include an insulating material, and may insulate the bit line BL and the word line WL from each other.

A gate insulation layer Gox may surround exposed surfaces of the word line WL and the spacer 140. The gate insulation layer Gox may conformally cover the word line WL and the spacer 140. The gate insulation layer Gox may cover an upper surface, a side surface, and a lower surface of the word line WL. The gate insulation layer Gox may cover an upper surface and a lower surface of the spacer 140.

The gate insulation layer Gox may be in contact with the bit line BL. A portion of the gate insulation layer Gox that covers an upper surface of the spacer 140 and an upper surface of the word line WL and a portion of the gate insulation layer Gox that covers the lower surface of the spacer 140 and the lower surface of the word line WL may be in contact with the bit line BL.

The gate insulation layer Gox may include at least one of a high-k dielectric layer, a silicon oxide layer, a silicon nitride layer, or a silicon oxide nitride layer. The high-k dielectric layer may include, for example, at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

The gate insulation layer Gox may include the first gate insulation layer Gox1 located between the first word line WL1 and the semiconductor pattern 200 and the second gate insulation layer Gox2 located between the second word line WL2 and the semiconductor pattern 200. The semiconductor pattern 200 may be spaced apart from the first word line WL1 by the first gate insulation layer Gox1. The semiconductor pattern 200 may be spaced apart from the second word line WL2 by the second gate insulation layer Gox2. The first gate insulation layer Gox1 may surround the first word line WL1, and the spacer 140 located between the first word line WL1 and the bit line BL. The second gate insulation layer Gox2 may surround the second word line WL2, and the spacer 140 located between the second word line WL2 and the bit line BL. The first gate insulation layer Gox1 and the second gate insulation layer Gox2 may be in contact with the bit line BL, respectively.

According to an embodiment, the semiconductor pattern 200 may be disposed between the pair of word lines WL, in each layer. The semiconductor pattern 200 may be disposed between the first word line WL1 and the second word line WL2. The semiconductor pattern 200 may be disposed between the first gate insulation layer Gox1 and the second gate insulation layer Gox2. A first end portion of the semiconductor pattern 200 may be connected to the bit line BL. A second end portion of the semiconductor pattern 200 may be connected to the data storage pattern DS. The semiconductor pattern 200 may be disposed within a space surrounded by an upper surface of the first gate insulation layer Gox1, a lower surface of the second gate insulation layer Gox2, and a side surface of the bit line BL.

According to an embodiment, at least the portion of the semiconductor pattern 200 may overlap with the substrate 110 in the third direction DR3 perpendicular to the pair of word lines WL.

An etch stop layer 130 may be located on a first side of the pair of word lines WL. The etch stop layer 130 may be located on a first side of the first word line WL1 and the second word line WL2. The etch stop layer 130 may be located on first side surfaces of the first gate insulation layer Gox1 and the second gate insulation layer Gox2. The etch stop layer 130 may be located on the side surface of the first gate insulation layer Gox1 that covers a side surface of the first word line WL1. The etch stop layer 130 may be located on a side surface of the second gate insulation layer Gox2 that covers a side surface of the second word line WL2. The etch stop layer 130 may include a portion located on the side surface of the first gate insulation layer Gox1 and a portion located on the side surface of the second gate insulation layer Gox2. The etch stop layer 130 may include portions separated in the third direction DR3.

The etch stop layer 130 may be in contact with the data storage pattern DS. According to an embodiment, an interface between the semiconductor pattern 200 and the data storage pattern DS and an interface between the etch stop layer 130 and the data storage pattern DS may be disposed on a straight line, but is not limited thereto. According to some embodiments, an interface between the semiconductor pattern 200 and the data storage pattern DS may be more adjacent to the bit line BL than an interface between the etch stop layer 130 and the data storage pattern DS. In this case, a portion of the data storage pattern DS may protrude toward the bit line BL and be located between portions of the etch stop layer 130 located on each of the side surfaces of the first gate insulation layer Gox1 and the second gate insulation layer Gox2. Depending the embodiment, the etch stop layer 130 may be omitted.

The data storage pattern DS may be electrically connected to the semiconductor pattern 200. The data storage pattern DS is a memory element capable of storing data, and may be, for example, a memory element using a capacitor, a memory element using a magnetic tunnel junction pattern, or a memory element using a variable resistor including a phase-change material.

According to an embodiment, the data storage pattern DS may be a capacitor. According to an embodiment, the data storage pattern DS may include the second electrode 330 spaced apart from the first electrode 310 and the first electrode 310, and the dielectric layer 320 located between the first electrode 310 and the second electrode 330.

According to an embodiment, the first electrode 310 may include a vertical portion extending in the third direction DR3 perpendicular to the substrate 110 and a pair of horizontal portions extending from the vertical portion in the second direction DR2 parallel to the substrate 110. The vertical portion of the first electrode 310 may be in contact with the semiconductor pattern 200 and the etch stop layer 130. The vertical portion of the first electrode 310 may cover a side surface of the etch stop layer 130 and a side surface of the semiconductor pattern 200, and may extend in the third direction DR3. A horizontal portion of the first electrode 310 may extend in the first direction DR1 from the vertical portion of the first electrode 310 to be away from the bit line BL. One among a pair of horizontal portions of the first electrode 310 may extend in the first direction DR1 along an upper surface of the second interlayer insulating layer 160 located below each layer, and the other one thereof may extend in the first direction DR1 along a lower surface of the second interlayer insulating layer 160 located above each layer. The pair of horizontal portions of the first electrode 310 may be spaced apart from the third direction DR3. The first electrode 310 may have a cylindrical shape extending in the first direction DR1.

According to an embodiment, the second electrode 330 may be inserted into the first electrode 310, and surrounded by the first electrode 310. The second electrode 330 may be inserted into an interior space of the first electrode 310 in a cylindrical shape. The data storage patterns DS of a plurality of layers stacked in the third direction DR3 may share one second electrode 330.

The first electrode 310 and the second electrode 330 may include at least one of a metallic material such as titanium, tantalum, tungsten, copper, or aluminum, a conductive metal nitride such as titanium nitride or tantalum nitride, or a doped semiconductor material such as doped silicon or doped germanium, respectively.

The dielectric layer 320 may be located between the first electrode 310 and the second electrode 330. The dielectric layer 320 may be conformally formed on the first electrode 310. The dielectric layer 320 may be located on an inner side of the first electrode 310, and may be located to surround the first electrode 310. The dielectric layer 320 may include at least one of a dielectric material, a ferromagnetic material, or an antiferromagnetic material. The dielectric material may include a high-k material. For example, the dielectric material may include hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or a combination thereof.

The support portion 400 may be located along the third direction DR3. End points of the pair of horizontal portions of the first electrode 310 may be located within the support portion 400. The support portion 400 may be in contact with the dielectric layer 320 and the second interlayer insulating layer 160. A description of the support portion 400 is the same as described above. A detailed description on the same components will be omitted. The support portion 400 may include an insulating material. For example, it may include a metal nitride, a metal oxide, or a metal carbide. The metal may be Si, Ti, Ta, Hf, Zr or Sr. That is, the support portion may include a nitride, oxide, or carbide material of Si, Ti, Ta, Hf, Zr, or Sr. The thickness D1 of the support portion 400 may be 50 Å to 200 Å. In addition, in the support portion 400, the width D2 of the region overlapping with the first electrode 310 may be wider than the width D3 of the region that does not overlap with the first electrode 310. The support portion 400 may be located in the shape of a single plate, and may be located in a separated form. In another embodiment, the support portion 400 may extend in the third direction DR3, and may be separated in the second direction DR2. In still another embodiment, the support portion 400 may extend along the second direction DR2 and be located to be separated in the third direction DR3.

As shown in FIG. 15 and FIG. 16, even if the first electrode 310 has a cylindrical shape, an end point of the horizontal portion of the first electrode 310 may be fixed by the support portion 400.

As described above, in the semiconductor device according to the present embodiment, the edge of the first electrode 310 may be fixed and capped by the support portion 400. Accordingly, the problem of the first electrode 310 sagging in the manufacturing process of the semiconductor device may be solved, and the problem of the etchant being introduced into the groove inside the first electrode 310 may be prevented.

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

### DESCRIPTION OF SYMBOLS

110: substrate 310: first electrode
320: dielectric layer 330: second electrode
400: support portion 500: mold
A1: transistor portion A2: data storage portion
BL: bit line WL: word line
DS: data storage pattern

What is claimed is:

1. A semiconductor device, comprising:
a substrate;
a bit line extending in a direction perpendicular to the substrate;
a plurality of semiconductor patterns having a first end portion connected to the bit line, and extending in a first direction;
a first electrode having a first end portion connected to the semiconductor pattern, and extending in the first direction; and
a support portion fixing a second end portion of the first electrode,
wherein the second end portion of the first electrode is located within the support portion.

2. The semiconductor device of claim 1, further comprising:
a dielectric layer surrounding the first electrode; and
a second electrode located on the dielectric layer, wherein the first electrode, the dielectric material and the second electrode form a capacitor.

3. The semiconductor device of claim 1, wherein a thickness of the support portion along the first direction is 50 Å to 200 Å.

4. The semiconductor device of claim 1, wherein a width of a region overlapping with the first electrode of the support portion along the first direction is wider than a width of a region that does not overlap with the first electrode of the support portion along the first direction.

5. The semiconductor device of claim 1, wherein:
the support portion comprises metal nitride, metal oxide or metal carbide; and
the metal is Si, Ti, Ta, Hf, Zr or Sr.

6. The semiconductor device of claim 1, wherein the support portion is extends in the direction perpendicular to the substrate.

7. The semiconductor device of claim 6, wherein the support portion comprises a plurality of support portions located to be spaced apart in a second direction transverse to the first direction.

8. The semiconductor device of claim 1, wherein a groove is located in an interior of the first electrode.

9. The semiconductor device of claim 8, wherein the groove is capped by the support portion.

10. The semiconductor device of claim 1, wherein the first electrode has a pillar shape extending along the first direction.

11. The semiconductor device of claim 1, wherein the first electrode comprises a vertical portion extending in the direction perpendicular to the substrate and a pair of horizontal portions extending from the vertical portion in the first direction parallel to the substrate.

12. A semiconductor device, comprising:
a substrate;
a bit line extending in a third direction perpendicular to the substrate;
a plurality of semiconductor patterns having first end portions connected to the bit line, and extending in a first direction transverse to the third direction;
a support portion extending in the third direction; and
a plurality of first electrodes, extending in the first direction, having first end portions connected to respective semiconductor patterns of the plurality of semiconductor patterns and second end portions are located within the support portion.

13. The semiconductor device of claim 12, wherein a thickness of the support portion along the first direction is 50 Å to 200 Å.

14. The semiconductor device of claim 12, wherein:
a width of a region overlapping with the first electrode of the support portion along the first direction is wider than a width of a region that does not overlap with the first electrode of the support portion along the first direction.

15. The semiconductor device of claim 12, wherein:
the support portion comprises metal nitride, metal oxide or metal carbide; and
the metal is Si, Ti, Ta, Hf, Zr or Sr.

16. The semiconductor device of claim 12, wherein the support portion comprises a plurality of support portions located to be spaced apart in a second direction transverse to both the first and third directions.

17. A semiconductor device, comprising:
a substrate;
a bit line extending in a third direction perpendicular to the substrate;
a plurality of semiconductor patterns having a first end portion connected to the bit line, and extending in a first direction parallel to the substrate;
a capacitor connected to the semiconductor pattern; and
a support portion extending in the third direction,
wherein the capacitor comprises:
a first electrode comprising a vertical portion extending in the third direction and a pair of horizontal portions extending from the vertical portion in the first direction;
a dielectric layer surrounding the first electrode; and
a second electrode located on the dielectric layer,
wherein end portions of a pair of horizontal portions of the first electrode are located within the support portion.

18. The semiconductor device of claim 17, wherein a thickness of the support portion along the first direction is 50 Å to 200 Å.

19. The semiconductor device of claim 17, wherein a width of a region overlapping with the first electrode of the support portion along the first direction is wider than a width of a region that does not overlap with the first electrode of the support portion along the first direction.

20. The semiconductor device of claim 17, wherein:
the support portion comprises metal nitride, metal oxide or metal carbide; and
the metal is Si, Ti, Ta, Hf, Zr or Sr.
